(19) United States
(12) Patent Application Publication
(10) Pub. No.: US 2023/0397335 A1
(43) Pub. Date: Dec. 7, 2023

(54) WIRING SUBSTRATE

(71) Applicant: IBIDEN CO., LTD., Ogaki (JP)

(72) Inventors: Toshiki FURUTANI, Ibi-gun (JP); Masashi KUWABARA, Ibi-gun (JP)

(73) Assignee: IBIDEN CO., LTD., Ogaki (JP)

(21) Appl. No.: 18/324,278

(22) Filed: May 26, 2023

(30) Foreign Application Priority Data
Jun. 7, 2022 (JP) 2022-092521

(51) Int. Cl. H05K 1/11; H05K 3/28; H05K 3/46

(52) U.S. Cl. CPC H05K 1/115; H05K 3/28; H05K 3/4644; H05K 2201/09563

(57) ABSTRACT

A wiring substrate includes an insulating layer, a first conductor layer formed on the insulating layer and including a first wiring and a second wiring formed adjacent to the first wiring, and a second conductor layer on the opposite side with respect to first conductor layer such that the insulating layer is covering the second conductor layer. The first conductor layer is formed such that each of the first wiring and the second wiring has an aspect ratio in the range of 2.0 to 4.0 and a wiring width of 5 μm or less and that the first wiring and the second wiring are separated by the distance of 7 μm or less, and the first conductor layer includes a seed layer formed on the insulating layer, and an electrolytic plating film formed on the seed layer.

### CROSS-REFERENCE TO RELATED APPLICATIONS

The present application is based upon and claims the benefit of priority to Japanese Patent Application No. 2022-092521, filed Jun. 7, 2022, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2000-87292 describes a method for manufacturing a printed wiring board including forming wiring patterns by forming an electroless plating layer on an interlayer resin insulating layer, applying electrolytic plating after forming a resist on the electroless plating layer, and removing the electroless plating layer by etching after removing the resist. The entire contents of this publication are incorporated herein by reference.

### SUMMARY OF THE INVENTION

According to one aspect of the present invention, a wiring substrate includes an insulating layer, a first conductor layer formed on the insulating layer and including a first wiring and a second wiring formed adjacent to the first wiring, and a second conductor layer on the opposite side with respect to first conductor layer such that the insulating layer is covering the second conductor layer. The first conductor layer is formed such that each of the first wiring and the second wiring has an aspect ratio in the range of 2.0 to 4.0 and a wiring width of 5 μm or less and that the first wiring and the second wiring are separated by a distance of 7 μm or less, and the first conductor layer includes a seed layer formed on the insulating layer, and an electrolytic plating film formed on the seed layer.

According to another aspect of the present invention, a method for manufacturing a wiring substrate includes forming a first conductor layer on an insulating layer such that the first conductor layer is formed on the opposite side with respect to a second conductor layer covered by the insulating layer and includes a first wiring and a second wiring separated by a distance of 7 μm or less and that each of the first and second wiring has an aspect ratio in the range of 2.0 to 4.0 and a wiring width of 5 μm or less. The forming of the first conductor layer includes forming a seed layer on the insulating layer, forming a plating resist on the seed layer, forming an electrolytic plating film on part of the seed layer exposed from the plating resist such that the electrolytic plating film has a thickness larger than a thickness of the plating resist, and polishing the electrolytic plating film and the plating resist such that the thickness of the electrolytic plating film and the thickness of the plating resist are reduced.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2A is a cross-sectional view illustrating an example of a manufacturing process of a wiring substrate according to an embodiment of the present invention;

FIG. 2B is a cross-sectional view illustrating an example of a manufacturing process of a wiring substrate according to an embodiment of the present invention;

FIG. 2C is a cross-sectional view illustrating an example of a manufacturing process of a wiring substrate according to an embodiment of the present invention;

FIG. 2D is a cross-sectional view illustrating an example of a manufacturing process of a wiring substrate according to an embodiment of the present invention;

FIG. 2E is a cross-sectional view illustrating an example of a manufacturing process of a wiring substrate according to an embodiment of the present invention;

FIG. 2F is a cross-sectional view illustrating an example of a manufacturing process of a wiring substrate according to an embodiment of the present invention;

FIG. 2G is a cross-sectional view illustrating an example of a manufacturing process of a wiring substrate according to an embodiment of the present invention;

FIG. 2H is a cross-sectional view illustrating an example of a manufacturing process of a wiring substrate according to an embodiment of the present invention;

FIG. 2I is a cross-sectional view illustrating an example of a manufacturing process of a wiring substrate according to an embodiment of the present invention;

FIG. 2J is a cross-sectional view illustrating an example of a manufacturing process of a wiring substrate according to an embodiment of the present invention;

FIG. 2K is a cross-sectional view illustrating an example of a manufacturing process of a wiring substrate according to an embodiment of the present invention;

FIG. 2L is a cross-sectional view illustrating an example of a manufacturing process of a wiring substrate according to an embodiment of the present invention;

FIG. 2M is a cross-sectional view illustrating an example of a manufacturing process of a wiring substrate according to an embodiment of the present invention;

FIG. 3A is a cross-sectional view illustrating an example of a manufacturing process of a wiring substrate according to another embodiment of the present invention;

FIG. 3B is a cross-sectional view illustrating an example of a manufacturing process of a wiring substrate according to another embodiment of the present invention;

FIG. 3C is a cross-sectional view illustrating an example of a manufacturing process of a wiring substrate according to another embodiment of the present invention; and

FIG. 3D is a cross-sectional view illustrating an example of a manufacturing process of a wiring substrate according to another embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

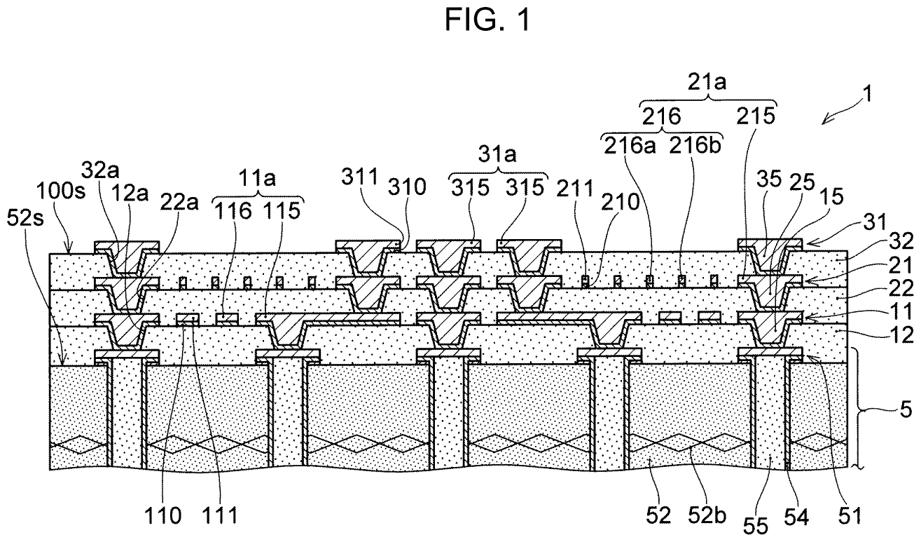

A wiring substrate according to an embodiment of the present invention is described with reference to the drawings. FIG. 1 is a cross-sectional view illustrating a wiring substrate 1, which is an example of the wiring substrate of the embodiment. The wiring substrate 1 is merely an example of the wiring substrate of the present embodiment. A laminated structure, and the number of conductor layers and the number of insulating layers of the wiring substrate of the embodiment are not limited to the laminated structure of the wiring substrate 1 of FIG. 1, and the number of the conductor layers and the number of the insulating layers included in the wiring substrate 1.

As illustrated in FIG. 1, the wiring substrate 1 includes: a core substrate 5; an insulating layer 12 that is laminated on one surface of the core substrate 5; a conductor layer 11 that is formed on the insulating layer 12; an insulating layer 22 that covers a surface of the insulating layer 12 not covered by the conductor layer 11 and covers the conductor layer 11; a conductor layer 21 that is formed on the insulating layer 22; an insulating layer 32 that covers a surface of the insulating layer 22 not covered by the conductor layer 21 and covers the conductor layer 21; and a conductor layer 31 that is formed on the insulating layer 32.

The core substrate 5 includes an insulating layer 52 and a conductor layer 51 formed on a surface (52s) on one side of the insulating layer 52. The core substrate 5 further includes through-hole conductors 54 penetrating the insulating layer 52, and includes, on the other surface (not illustrated in the drawings) of the insulating layer 52, a conductor layer (not illustrated in the drawings) similar to the conductor layer 51. The conductor layer 51 is connected to the conductor layer (not illustrated in the drawings) on the other surface of the insulating layer 52 by the through-hole conductors 54. Inner sides of the through-hole conductors 54 are each filled with a resin body 55 containing an epoxy resin or the like. The conductor layer 51 has a multilayer structure including a lower layer formed of a metal foil on the insulating layer 52, a middle layer integrally formed with the through-hole conductors 54, and an upper layer covering the resin body 55. Although not illustrated in the drawings, the wiring substrate 1 can include any number of conductor layers containing any conductor patterns and any number of insulating layers laminated or formed on the surface on the opposite side with respect to the surface (52s) of the insulating layer 52.

In the description of the embodiment, a side farther from the insulating layer 52 in a thickness direction (lamination direction) of the wiring substrate 1 is also referred to as an “outer side,” “upper side,” or simply “upper,” and a side closer to the insulating layer 52 is also referred to as an “inner side,” a “lower side,” or simply “lower.” Further, for the conductor layers and the insulating layers, a surface facing the opposite side with respect to the insulating layer 52 is also referred to as an “upper surface,” and a surface facing the insulating layer 52 side is also referred to as a “lower surface.”

The conductor layers (11, 21, 31, 51) each include any conductor patterns. For example, in the example of FIG. 1, the conductor layer 21 (first conductor layer) includes conductor patterns (21a). The conductor layer 11 (second conductor layer) includes conductor patterns (11a). Further, in the example of FIG. 1, the conductor layers (11, 21, 31) are formed to each have a two-layer structure. In each of the insulating layers (12, 22, 32), connection conductors (via conductors) (15, 25, 35) that penetrate the each of the insulating layers and connect conductor layers that are adjacent to each other via the each of the insulating layers are formed. For example, in the example of FIG. 1, in the insulating layer 22 (first insulating layer), the via conductors 25 (first via conductors) that connect the conductor layer 11 and the conductor layer 21 are formed. The insulating layers (22, 32) respectively cover the upper surface of the conductor layer 11 on the opposite side with respect to the insulating layer 12 and the upper surface of the conductor layer 21 on the opposite side with respect to the insulating layer 22. Further, the insulating layers (22, 32) respectively cover side surfaces of the conductor patterns (11a) included in the conductor layer 11 and the conductor patterns (21a) included in the conductor layer 21.

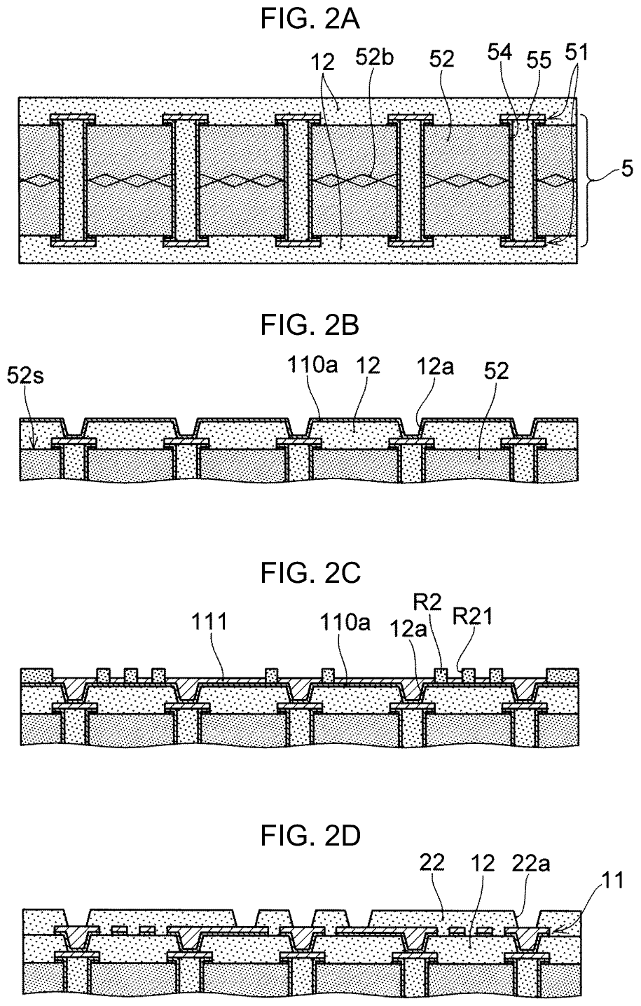

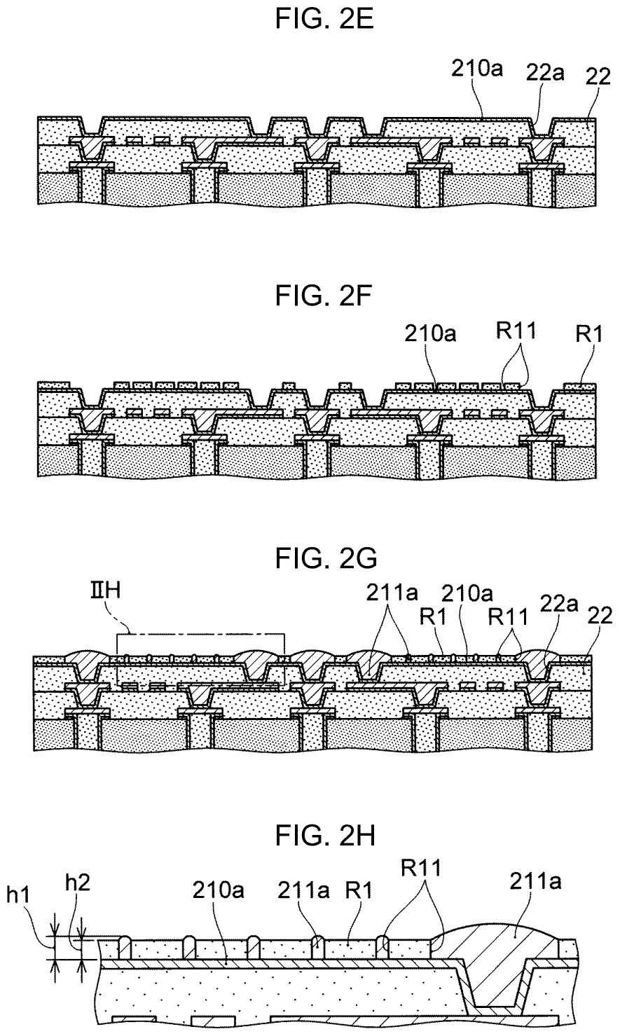

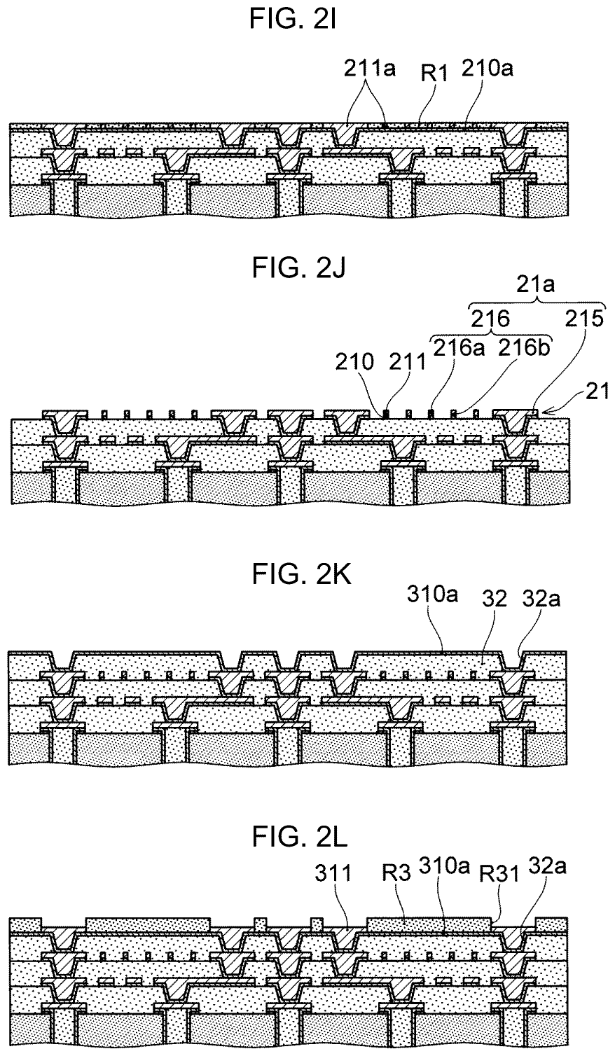

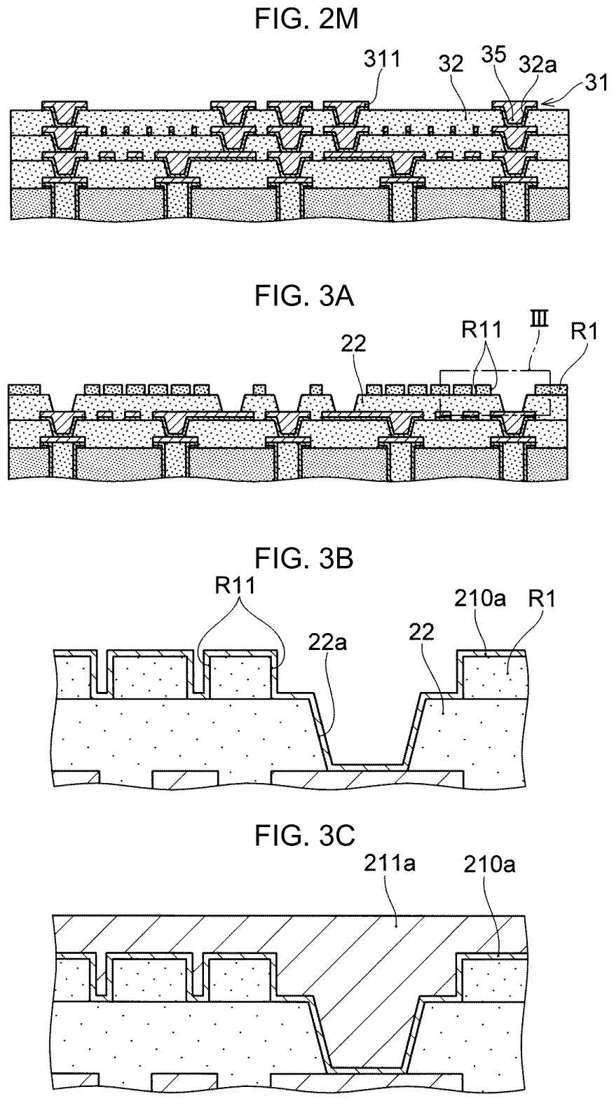

In the embodiment of the wiring substrate 1 illustrated in FIG. 1, in forming the via conductors 25 in the insulating layer 22, for example, first, through holes (22a) (first through holes) are formed at positions where the via conductors 25 of the insulating layer 22 are to be formed, for example, by irradiating CO₂ laser from the surface side of the insulating layer 22 (see FIG. 2D). The through holes (22a) in which the via conductors 25 are to be formed are formed such that, for example, an aspect ratio of the via conductors ((the depth from the surface of the insulating layer 22 to the bottom of each of the through holes (22a))/(the diameter of each of the through holes (22a) on the surface side of the insulating layer 22) is about 0.5 or more and about 1.0 or less.

As described above, in the embodiment of FIG. 1, the conductor layers (11, 21, 31) of the wiring substrate 1 are formed to each have a two-layer structure. For example, the conductor layer 21 includes a lower layer 210 formed on the surface of the insulating layer 22 on the insulating layer 32 side and an upper layer 211 formed on the lower layer 210. That is, first, in order to form the lower layer 210 of the conductor layer 21, on inner walls of the through holes (22a) and on the surface of the insulating layer 22, a metal film (210a) (see FIG. 2E) constituting the lower layer 210 of the conductor layer 21 is formed, for example by sputtering.

To form the upper layer 211 of the conductor layer 21, on the formed metal film (210a), a plating resist (R1) (see FIG. 2F) having openings (R11) corresponding to the conductor patterns (21a) included in the conductor layer 21 is provided, for example by lamination of a dry film resist and exposure and development or the like. The upper layer 211 of the conductor layer 21 is formed by filling the openings (R11) of the plating resist (R1) with an electrolytic plating film using the metal film (210a) as a seed layer. As illustrated in FIG. 1, in the wiring substrate 1 of the embodiment, the conductor layer 21 includes the wiring patterns (21a) including via lands 215, which are integrally formed with the via conductors 25, and wiring patterns 216, which are formed of wirings having relatively small widths and high aspect ratios. For example, the wirings (first wirings (216a) and second wirings (216b)) included in the wiring patterns 216 have a minimum wiring width of 5 μm or less and a minimum wiring spacing (that is, a distance between a first wiring (216a) and a second wiring (216b)) of 7 μm or less. Specifically, for example, in the wiring patterns 216, the wiring widths of the first wirings (216a) and the second wirings (216b) are about 1 μm or more and about 5 μm or less. On the other hand, for example, the other wirings included in the conductor layer 21 and/or wirings included in other conductor layers, for example, the conductor layer 11, have a minimum wiring width of about 7 μm or less.

Since the wiring substrate 1 has the wiring patterns 216, it may be possible to provide wirings that have a more suitable characteristic impedance for electrical signals that can be transmitted. Further, it is thought that it may be possible to improve a wiring density and to further improve a degree of freedom in wiring design. From the same point of view, the aspect ratios of the wirings such as the first wirings (216a) or the second wirings (216b) included in the wiring patterns 216 can be formed larger than the aspect ratios of the other wirings included in the conductor layer 21 and/or wirings included in the other conductor layers, for example, the conductor layer 11. For example, the aspect ratios of the wirings such as the first wirings (216a) or the second wirings (216b) included in the wiring patterns 216 are preferably about 2.0 or more and about 4.0 or less. On the other hand, for example, the aspect ratios of the other wirings included in the conductor layer 21 and/or the wirings included in the other conductor layers, for example, the conductor layer 11, can be, for example, about 1.5 or more and about 3.0 or less.

To form wiring conductors with such small wiring widths and high aspect ratios, deep openings (R11) are formed in the plating resist (R1) with high accuracy for forming the upper layer 211 of the wiring patterns 216. Further, in order to prevent a defect such as a short circuit between wirings of the wiring patterns 216, side walls of the openings (R11) are formed substantially perpendicular to a planar direction of the wiring substrate 1 (a direction perpendicular to the thickness direction of the wiring substrate 1). However, when a thick plating resist (R1) is used as the aspect ratios of the wirings of the wiring patterns 216 increase, even when an exposure condition and the like are adjusted, it can be difficult to form the openings (R11) corresponding to the wirings of the wiring patterns 216 in the plating resist (R1) in appropriate shapes by exposure and development. In particular, as the side walls of the openings (R11) become higher, it is thought that there is a risk that side walls of the plating resist (R1) forming the openings (R11) may have a tapered undercut shape that widens toward the surface of the metal film (seed layer) (210a).

To form the upper layer 211 of the wiring patterns 216 having a two-layer structure on the lower layer 210, an electrolytic plating film forming the upper layer 211 is formed on the metal film (210a) in the openings (R11) by electrolytic plating using the metal film (210a) as a power feeding layer. That is, the openings (R11) of the plating resist (R1) can be filled with the electrolytic plating film. Therefore, when the openings (R11) are formed such that the side walls of the plating resist (R1) forming the openings (R11) have, for example, a tapered undercut shape, there is a possibility that the wirings included in the wiring patterns 216 cannot be formed with a uniform wiring width. Further, in filling the openings (R11) with the electrolytic plating film, the openings (R11) of the plating resist (R1) are usually not completely filled. According to a general method for forming wiring conductors, the plating resist (R1) is formed to be thicker than the upper layer 211 of the wiring patterns 216. That is, when the wirings included in the wiring patterns 216 have high aspect ratios, the openings (R11) of the plating resist (R1) are formed to have higher aspect ratios than the wirings included in the wiring patterns 216. It is thought that the above-described problem related to the shape of the side walls of the openings (R11) is more likely to occur.

In the present embodiment, an electrolytic plating film (211a) formed by electrolytic plating using the metal film (210a) as a power feeding layer is formed thicker than the plating resist (R1) (see FIGS. 2G and 2H). It is not necessary to form a thick plating resist (R1) and provide deep openings (R11) in the plating resist (R1). Further, since the plating resist (R1) does not become thick, openings (R11) having appropriate shapes such that the side walls of the openings (R11) are substantially perpendicular to the planar direction of the wiring substrate 1 can be formed. By filling such openings (R11) with the electrolytic plating film (211a), the conductor patterns (21a) of the conductor layer 21, in particular, the upper layer 211 of the wiring patterns 216, are formed. Therefore, it is thought that the wiring patterns 216 including the wirings having high aspect ratios are formed with high accuracy. The side walls of the wirings included in the wiring patterns 216 are formed along the substantially vertical side walls of the openings (R11) and thus are substantially perpendicular to the planar direction of the wiring substrate 1. Therefore, it is thought that there is no risk of causing a defect such as a short circuit between the wirings of the wiring patterns 216. For example, the electrolytic plating film (211a) can be formed thicker than the plating resist (R1) by 1 μm or more. The electrolytic plating film (211a) completely fills the through holes (22a) of the insulating layer 22. As a result, the via conductors 25 are formed and the via lands 215 are integrally with the via conductors 25.

After that, a part of the electrolytic plating film (211a) in the thickness direction is removed by polishing. For example, a part of the electrolytic plating film (211a) is removed by chemical mechanical polishing (CMP) or sandblasting. By this polishing, a part of the plating resist (R1) in the thickness direction is also removed. Specifically, the electrolytic plating film (211a) is polished together with the plating resist (R1) until a predetermined thickness required for the upper layer 211 of the conductor layer 21 is reached. Therefore, after the electrolytic plating film (211a) is formed, for example as illustrated in FIG. 2H, even when the surface has unevenness, the upper surface of the upper layer 211 of the conductor layer 21 that has been subjected to polishing is flattened. Further, it is thought that adjustment of the thickness of the upper layer 211 of the conductor layer 21 is also easy.

When the upper surface of the conductor layer 21 is a flattened polished surface with less unevenness, for example, it may be possible that, in the wiring patterns 216, good high-frequency transmission characteristics can be obtained. Further, since the surfaces of the via lands 215 integrally formed with the via conductors 25 are highly flat polished surfaces, as illustrated in FIG. 1, when the via conductors 35 are formed so as to overlap the via conductors 25 in a plan view, it is thought that good connectivity with the via conductors 35 can be provided. Further, since the entire upper surface of the conductor layer 21 is polished, the conductor layer 21 having a uniform thickness can be obtained regardless of the unevenness or density of the conductor layer 21. In the manufacturing of the laminated structure of the wiring substrate 1, occurrence of misalignment or the like can be suppressed. It is thought that a wiring substrate 1 with high connection reliability can be provided. Further, it is thought that it is possible to reduce planar sizes of the via conductors and the via lands while maintaining high connection reliability. As a result, in the wiring substrate 1, for example, the via conductors 25 having relatively small diameters with aspect ratios of about 0.5 or more and about 1.0 or less can be provided.

That the via conductors 25 and the via conductors 35 “overlap in a plan view” means that bottoms of the via conductors 35 in contact with the upper surface of the conductor layer 21 are contained in openings of the through holes (22a) at an interface between the insulating layer 22 and the conductor layer 21. Further, “plan view” means viewing the wiring substrate of the embodiment along the thickness direction thereof.

After that, the plating resist (R1) is removed, and a portion of the metal film (210a) that is not covered by the upper layer 211 is removed by etching or the like. The conductor layer 21 illustrated in FIG. 1 is obtained that has a two-layer structure formed of the lower layer 210 and the upper layer 211 and includes the conductor patterns (21a) such as the wiring patterns 216, which include the first wirings (216a) and the second wirings (216b), and the via lands 215. Since the upper layer 211 of the conductor layer 21 can be formed without using a thick plating resist (R1), the wiring substrate 1 can be formed that includes the wiring patterns 216 formed of the wirings having sidewalls substantially perpendicular to the planar direction and high aspect ratios, which were conventionally difficult to obtain. As described above, the upper surface of the conductor layer 21 is a polished surface. Therefore, the surface of the conductor layer 21, which includes the conductor patterns (21a), has excellent flatness.

In the following, the wiring substrate 1 of the embodiment is further described in detail by referring to an example of a method for manufacturing the wiring substrate illustrated in FIGS. 2A-2M.

As illustrated in FIG. 2A, the core substrate 5 is prepared that includes the insulating layer 52 and the conductor layer 51 on both sides of the insulating layer 52, and the insulating layer 12 is formed on both sides of the core substrate 5. For example, through holes for forming the through-hole conductors 54 are formed in a double-sided copper-clad laminated plate, and a metal film is formed on inner walls of the through holes and on surfaces of the double-sided copper-clad laminated plate by electroless plating or sputtering, and electrolytic plating or the like. The through-hole conductors 54 formed of a metal film are formed in the through holes. Inner sides of the through-hole conductors 54 are filled with the resin bodies 55, for example, by injecting an epoxy resin. Then, a metal film is further formed on the previously formed metal film and the resin bodies 55 by electroless plating or electrolytic plating. Then, the conductor layer 51 of a multilayer structure having predetermined conductor patterns is formed on both sides of the insulating layer 52 by patterning using a subtractive method. For example, the core substrate 5 is prepared in this way, and then the insulating layer 12 is formed on both sides of the core substrate 5.

The insulating layer 52 and the insulating layer 12, as well as the insulating layers (22, 32) (see FIG. 1), each contain any insulating resin. Examples of the insulating resin include: thermosetting resins such as epoxy resins, bismaleimide triazine resins (BT resins), or phenolic resins; and thermoplastic resins such as fluorine resins, liquid crystal polymers (LCP), fluoroethylene (PTFE) resins, polyester (PE) resins, and modified polyimide (MPI) resins. The insulating layers may contain the same insulating resin or may contain different insulating resins from each other. Further, the insulating layers may each contain a core material (reinforcing material) formed of a glass fiber or an aramid fiber. In the example of FIG. 1 the insulating layer 52 contains a core material (52b). The insulating layers can each further contain an inorganic filler (not illustrated in the drawings) formed of fine particles of silica (SiO2), alumina, mullite, or the like. An insulating layer containing such an inorganic filler can have, for example, a thermal expansion coefficient close to that of a conductor layer, and thus may be preferable.

For example, the insulating layer 12 is formed by laminating and thermocompression bonding a film-like epoxy resin. Next, as illustrated in FIG. 2B, through holes (12a) are formed in the insulating layer 12 at positions where the via conductors 15 (see FIG. 1) are to be formed, for example, by irradiating CO₂ laser. Then, a metal film (110a) forming the lower layer 110 (see FIG. 1) of the conductor layer 11 is formed on inner walls of the through holes (12a) and the surface of the insulating layer 12 by electroless plating or sputtering or the like. In FIGS. 1 and 2B, as well as FIGS. 2C-2G and 2I-2M referred to below, the illustration of the conductor layers and the insulating layers that can be formed on the surface on the opposite side with respect to the surface (52s) on one side of the insulating layer 52 is omitted and description thereof is also omitted. However, on the opposite side with respect to the surface (52s), conductor layers and insulating layers may be formed in the same manner and number as those on the surface (52s) or in different manner and number from those on the surface (52s), or it is also possible that such conductor layers and insulating layers are not formed.

As illustrated in FIG. 2C, a plating resist (R2) having openings (R21) corresponding to the conductor patterns (11a) included in the conductor layer 11 is provided on the metal film (110a) by, for example, lamination of a dry film resist and exposure and development. Then, an upper layer 111 of the conductor layer 11 is formed in the openings (R21) and in the through holes (12a) by electrolytic plating using the metal film (110a) as a power feeding layer. After that, the plating resist (R2) is removed, and a portion of the metal film (110a) that is not covered by the upper layer 111 is removed by etching or the like. As a result, as illustrated in FIG. 1, the via conductors 15 are formed in the through holes (12a) penetrating the insulating layer 12, and the conductor layer 11 is formed to include the conductor patterns (11a) including via lands 115, which are integrally formed with the via conductors 15, multiple wiring patterns 116, and the like. The via conductors 15 are integrally formed with the conductor layer 11 and connect conductor layer 11 and the conductor layer 51.

The conductor layers (11, 21, 31, 51), the via conductors (15, 25, 35), and the through-hole conductors 54 can be formed using any metal such as copper or nickel.

After the conductor layer 11 and the via conductors 15 are formed, the insulating layer 22 is laminated and as described above, the conductor layer 21 is formed on the insulating layer 22 and the via conductors 25 are formed penetrating the insulating layer 22. Specifically, as illustrated in FIG. 2D, similar to the insulating layer 12, the insulating layer 22 can be formed on the surface of the insulating layer 12 that is not covered by the conductor layer 11 and on the conductor layer 11 by laminating a film-like resin containing an epoxy resin or the like and applying heat and pressure thereto.

As in the wiring substrate 1 of the embodiment, when the conductor patterns (21a) including the wiring patterns 216 in which wirings can be formed at a fine pitch are formed in the conductor layer 21, it may be preferable for the via conductors 25 to be formed also at a fine pitch. The through holes (22a) for the via conductors 25 are formed with small diameters in the insulating layer 22. In such a case, to facilitate the formation of the through holes (22a) with small diameters, an insulating layer 22 that does not contain an inorganic filler may be preferable.

A resin that does not contain an inorganic filler is unlikely to have a thermal expansion coefficient close to that of a conductor layer formed of a metal such as the conductor layer 21. Therefore, when the insulating layer 22 does not contain an inorganic filler, it may be preferable that the insulating layer 22 is not exposed to high temperatures, for example, during curing or the like of the insulating layer 22. For example, the insulating layer 22 may be formed of a resin having a curing mechanism other than thermosetting, for example, a photocurable resin. In this case, for example, a film-like resin formed of a photosensitive resin containing a photopolymerization initiator or the like can be used to form the insulating layer 22. A high temperature curing process of the insulating layer 22 can be avoided.

Next, the through holes (22a) are formed in the insulating layer 22 at the formation positions of the via conductors 25 (see FIG. 1). The formation of the through holes (22a) in the insulating layer 22 can be performed, for example, by irradiation with CO₂ laser, excimer laser, or the like. Although not illustrated, the formation of the through holes (22a) by irradiation of laser such as CO₂ laser can be performed by irradiating laser while protecting the surface of the insulating layer 22 by covering the surface with a protective film such as a polyethylene terephthalate (PET) film. The through holes (22a) penetrating the protective film and the insulating layer 22 are formed. Further, after the through holes (22a) are formed, a desmear treatment may be performed to prevent a decrease in adhesion or an increase in a resistance component or the like during the formation of the conductor layer 21 due to a processing-deformed substance occurring at bottoms of the through holes (22a). The desmear treatment can preferably be a dry desmear treatment using a plasma gas. Further, the desmear treatment may also be performed while protecting the surface of the insulating layer 22 in a state in which a protective film such as a polyethylene terephthalate (PET) film is formed on the surface of the insulating layer 22. When the insulating layer 22 is formed using a photosensitive resin, the through holes (22a) may be formed by exposure and development using an exposure mask having openings corresponding to the through holes (22a).

Next, as illustrated in FIG. 2E, the metal film (seed layer) (210a) is formed on the inner walls of the through holes (22a) and on the surface of the insulating layer 22 by electroless plating or sputtering or the like. Preferably, the metal film (210a) can be a sputtering film formed by sputtering. When a protective film is provided on the surface of the insulating layer 22 during the formation of the through holes (22a) and/or during the desmear treatment, the protective film can be peeled off before the formation of the metal film (210a).

As illustrated in FIG. 2F, the plating resist (R1) having the openings (R11) corresponding to the conductor patterns (21a) included in the conductor layer 21 is provided on the metal film (210a). The plating resist (R1) can be provided in the same way as the plating resist (R2). However, as described above, unlike the plating resist (R2), the plating resist (R1) does not need to be thicker than the electrolytic plating film (211a) (see FIG. 2G) forming the upper layer 211 of the conductor layer 21.

As illustrated in FIG. 2G, the electrolytic plating film (211a) is formed with a height higher than that of the plating resist (R1) in the openings (R11) of the plating resist (R1) by electrolytic plating using the metal film (210a) as a power feeding layer. FIG. 2H illustrates an enlarged view of the embodiment corresponding to a portion (IIH) illustrated in FIG. 2G in a state in which the electrolytic plating film (211a) is filled in the openings (R11). The electrolytic plating film (211a) is formed to have a height higher than that of the openings (R11) and is formed, for example, to have a convex spherical surface that protrudes upward. For example, the plating resist (R1) can be formed to have a thickness of about 7 μm or more and 25 μm or less. Preferably, for example, a height (h1) of a top part of the electrolytic plating film (211a), which is filled in the openings (R11) for forming the wiring patterns 216 including the first wirings (216a) and the second wirings (216b), from the metal part (210a) can be formed to be higher than a thickness (h2) of the plating resist (R1) by 1 μm or more.

Next, as illustrated in FIG. 2I, a part of the electrolytic plating film (211a) and a part of the plating resist (R1) are removed by polishing. The polishing can be performed until the thickness of the electrolytic plating film (211a) reaches a predetermined thickness required for the upper layer 211 of the conductor layer 21. For example, the thickness of the conductor layer 21 can be about 7 μm or more and 20 μm or less. Then, the thickness of the upper layer 211 of the two-layer structure of the conductor layer 21 can be, for example, 6.5 μm or more.

As illustrated in FIG. 2J, after the plating resist (R1) is removed, a portion of the metal film (210a) that is not covered by the upper layer 211 is removed by etching or the like. As a result, the conductor layer 21 is formed that has a two-layer structure formed of the lower layer 210 and the upper layer 211 and includes the conductor patterns (21a) such as the via lands 215 and the wiring patterns 216 in which the first wirings (216a) and the second wirings (216b) with high aspect ratios are formed.

As illustrated in FIG. 2K, the insulating layer 32 is formed. The insulating layer 32 can be formed, for example, using the same method as the method for forming the insulating layer 12 described above. In the insulating layer 32, through holes (32a) for the via conductors 35 penetrating the insulating layer 32 are formed at formation positions of the via conductors 35. After that, a metal film (310a) forming a lower layer 310 (see FIG. 1) of the conductor layer 31 is formed on inner walls of the through holes (32a) and the surface of the insulating layer 32, for example, by electroless plating or sputtering or the like.

As illustrated in FIG. 2L, similar to the formation of the plating resist (R2), a plating resist (R3) having openings (R31) corresponding to the conductor patterns included in the conductor layer 31 is provided on the metal film (310a). Similar to the formation of the upper layer 111 of the conductor layer 11, an upper layer 311 of the conductor layer 31 is formed in the openings (R31) and in the through holes (32a) by electrolytic plating.

As illustrated in FIG. 2M, the conductor layer 31 is formed on the insulating layer 32 by removing the plating resist (R3) and removing a portion of the metal film (310a) that is not covered by the upper layer 311 by etching or the like. The via conductors 35 are formed by completely filling the through holes (32a) with an electrolytic plating film. In the example of FIG. 1, the conductor layer 31 includes conductor patterns (31a) including via lands 315 that are integrally formed with the via conductors 35. That is, the conductor layer 31 includes the via lands 315 that are connected to the via conductors 35. In the example illustrated in FIG. 1, a surface formed by the insulating layer 32 and the conductor layer 31 forms one (first surface (100s)) of two surfaces of the wiring substrate 1 (surfaces perpendicular to the thickness direction of the wiring substrate 1). When the wiring substrate 1 is used, a component (not illustrated in the drawings) to be mounted on the wiring substrate 1 can be placed on the first surface (100s). That is, the first surface (100s) of the wiring substrate 1 can be a component mounting surface. Therefore, the via lands 315 may be component mounting via pads to be used as connecting parts when an external component is mounted on the wiring substrate 1.

Through the above processes, the formation of the wiring substrate 1 illustrated in FIG. 1, which is provided with the conductor layer 21 that includes the conductor patterns (21a) including the wiring patterns 216 in which wirings having high aspect ratios are formed, is completed.

The wiring substrate of the embodiment is not limited to those having the structures illustrated in the drawings and those having the structures, shapes, and materials exemplified herein. For example, the wiring substrate can have any number of resin insulating layers and any number of conductor layers. Further, the wiring substrate is not limited to the mode of having a core substrate, and the wiring substrate of the embodiment only needs to have at least a structure that includes the insulating layer 22 and the conductor layer 21.

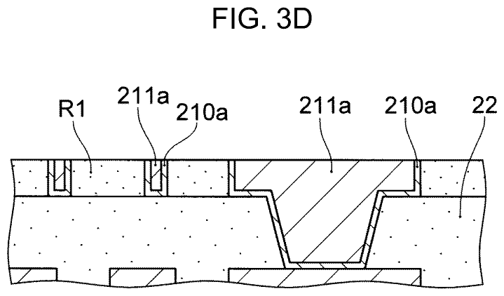

In the description of the embodiment, an example is described in which, in the formation of the conductor layer 21, the metal film (seed layer) (210a) is formed on the inner walls of the through holes (22a) and the entire surface of the insulating layer 22, and the plating resist (R1) having the openings (R11) is provided thereon. However, it is also possible that the plating resist (R1) is first provided on the surface of the insulating layer 22, and, after that, the metal film (seed layer) (210a) is formed on the inner walls of the through holes (22a) and on the surface of the insulating layer 22 that is not covered by the plating resist (R1), and on the surface of the plating resist (R1) and on the inner walls of the openings (R11) of the plating resist (R1). This example is illustrated in FIGS. 3A-3D.

For example, as illustrated in FIG. 3A, the plating resist (R1) having the openings (R11) is provided on the surface of the insulating layer 22. Subsequently, as illustrated in FIG. 3B, the metal film (210a) is formed on the inner walls of the through holes (22a) and on the surface of the insulating layer 22 that is not covered by the plating resist (R1), and on the surface of the plating resist (R1) and on the inner walls of the openings (R11) of the plating resist (R1). FIGS. 3B-3D each illustrate an enlarged view of a portion corresponding to a portion (III) illustrated in FIG. 3A. Subsequently, as illustrated in FIG. 3C, the electrolytic plating film (211a) is formed on the entire upper surface of the metal film (210a) by electrolytic plating using the metal film (210a) as a power feeding layer. After that, as illustrated in FIG. 3D, a part of the electrolytic plating film (211a) in the thickness direction is removed together with at least a portion of the metal film (210a) on the surface of the plating resist (R1) and the plating resist (R1). After that, by removing the plating resist (R1) from the surface of the insulating layer 22, the conductor layer 21 formed of the metal film (210a) and the electrolytic plating film (211a) can be formed.

When the conductor layer 21 is formed in this way, a portion of the surface of the insulating layer 22 that is exposed without being covered by the conductor patterns (21a) has not gone through a process of forming the metal film (210a) thereon, and thus is not a surface from which a conductor such as the metal film (210a) has been removed. Therefore, it is thought that there are no residues of conductors or the like on the surface of the insulating layer 22, and thus, even when wirings are formed at a fine pitch on the insulating layer 22, a defect such as a short circuit between the wirings is not caused. Further, in this case, of the two layers forming the conductor layer, the upper layer is not exposed on side surfaces of the conductor patterns, and the lower layer that forms lower surfaces is formed so as to cover side surfaces of the upper layer (see FIG. 3D). Therefore, the wiring substrate of the embodiment may include, in a conductor layer, conductor patterns in which side surfaces of the conductor patterns are formed by a lower layer forming a lower surface of the conductor layer, and side surfaces of an upper layer are covered by the lower layer.

Japanese Patent Application Laid-Open Publication No. 2000-87292 describes a method for manufacturing a printed wiring board including forming wiring patterns by forming an electroless plating layer on an interlayer resin insulating layer, applying electrolytic plating after forming a resist on the electroless plating layer, and removing the electroless plating layer by etching after removing the resist. The electrolytic plating is performed intermittently with the electroless plating layer as a cathode and a metal to be plated as an anode while maintaining a constant voltage between the anode and the cathode.

In the method for manufacturing a printed wiring board of Japanese Patent Application Laid-Open Publication No. 2000-87292, it is thought that there is a risk that variation in thicknesses of the wiring patterns may occur.

A wiring substrate according to an embodiment of the present invention includes: a second conductor layer; a first insulating layer that covers the second conductor layer; and a first conductor layer that is formed on the first insulating layer and includes a first wiring and a second wiring adjacent to the first wiring. The first wiring and the second wiring each have an aspect ratio of 2.0 or more and 4.0 or less. The first wiring and the second wiring each have a wiring width of 5 μm or less. A distance between the first wiring and the second wiring is 7 μm or less. Forming the first conductor layer includes: forming a seed layer on the first insulating layer; forming a plating resist on the seed layer; forming an electrolytic plating film having a thickness larger than a thickness of the plating resist on the seed layer exposed from the plating resist; and reducing the thickness of the electrolytic plating film and the thickness of the plating resist by polishing.

According to an embodiment of the present invention, a wiring board with high connection reliability including wirings with high aspect ratios can be provided.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
an insulating layer;
a first conductor layer formed on the insulating layer and including a first wiring and a second wiring formed adjacent to the first wiring; and
a second conductor layer on an opposite side with respect to first conductor layer such that the insulating layer is covering the second conductor layer,
wherein the first conductor layer is formed such that each of the first wiring and the second wiring has an aspect ratio in a range of 2.0 to 4.0 and a wiring width of 5 μm or less and that the first wiring and the second wiring are separated by a distance of 7 μm or less, and the first conductor layer includes a seed layer formed on the insulating layer, and an electrolytic plating film formed on the seed layer.

2. The wiring substrate according to claim 1, further comprising:
a first via conductor comprising the electrolytic plating film filling in a through hole in the insulating layer such that the via conductor is connecting the first conductor layer and the second conductor layer.

3. The wiring substrate according to claim 2, wherein the via conductor has an aspect ratio in a range of 0.5 to 1.0.

4. The wiring substrate according to claim 1, wherein the first conductor layer has a thickness in a range of 7 μm to 20 μm.

5. The wiring substrate according to claim 1, wherein the seed layer includes a sputtering film.

6. The wiring substrate according to claim 2, wherein the first conductor layer has a thickness in a range of 7 μm to 20 μm.

7. The wiring substrate according to claim 2, wherein the seed layer includes a sputtering film.

8. The wiring substrate according to claim 3, wherein the first conductor layer has a thickness in a range of 7 μm to 20 μm.

9. The wiring substrate according to claim 3, wherein the seed layer includes a sputtering film.

10. The wiring substrate according to claim 1, wherein the first conductor layer is formed by forming the seed layer on the insulating layer, forming a plating resist on the seed layer, forming the electrolytic plating film on part of the seed layer exposed from the plating resist such that the electrolytic plating film has a thickness larger than a thickness of the plating resist, and polishing the electrolytic plating film and the plating resist such that the thickness of the electrolytic plating film and the thickness of the plating resist are reduced.

11. A method for manufacturing a wiring substrate, comprising:
forming a first conductor layer on an insulating layer such that the first conductor layer is formed on an opposite side with respect to a second conductor layer covered by the insulating layer and includes a first wiring and a second wiring separated by a distance of 7 μm or less and that each of the first and second wiring has an aspect ratio in a range of 2.0 to 4.0 and a wiring width of 5 μm or less,
wherein the forming of the first conductor layer includes forming a seed layer on the insulating layer, forming a plating resist on the seed layer, forming an electrolytic plating film on part of the seed layer exposed from the plating resist such that the electrolytic plating film has a thickness larger than a thickness of the plating resist, and polishing the electrolytic plating film and the plating resist such that the thickness of the electrolytic plating film and the thickness of the plating resist are reduced.

12. The method of claim 11, wherein the forming of the first conductor layer includes forming the thickness of the electrolytic plating film larger than the thickness of the plating resist by 1 μm or more.

13. The method of claim 11, further comprising:
forming a through hole in the insulating layer such that the through hole penetrates through the insulating layer,
wherein the forming of the electrolytic plating film includes filling the electrolytic plating film into the through hole such that a via conductor comprising the electrolytic film is formed in the through hole and connects the first conductor layer and the second conductor layer.

14. The method of claim 13, wherein the through hole is formed such that the via conductor has an aspect ratio in a range of 0.5 to 1.0.

15. The method of claim 11, wherein the first conductor layer is formed such that the first conductor layer has a thickness in range of 7 μm to 20 μm.

16. The method of claim 11, wherein the forming of the seed layer includes forming the seed layer comprising a sputtering film.

17. The method of claim 13, wherein the forming of the through hole includes covering a surface of the insulating layer with a protective film, and forming the through hole such that the through hole penetrates through the protective film and the insulating layer.

18. The method of claim 17, wherein the forming of the through hole includes applying a plasma gas to the through hole such that the through hole is cleaned by the plasma gas.

19. The method of claim 18, wherein the plasma gas is applied to the insulating layer having the protective film formed thereon.

20. The method of claim 12, further comprising:
forming a through hole in the insulating layer such that the through hole penetrates through the insulating layer,
wherein the forming of the electrolytic plating film includes filling the electrolytic plating film into the through hole such that a via conductor comprising the electrolytic film is formed in the through hole and connects the first conductor layer and the second conductor layer.
